(19) United States
(12) Patent Application Publication
(10) Pub. No.: US 2012/0326185 A1
(43) Pub. Date: Dec. 27, 2012

(54) LIGHT EMITTING DEVICE

(75) Inventors: Ming-Te LIN, Chuntung Chen (TW); Hsi-Hsuan YEN, Chutung Chen (TW); Ming-Yao LIN, Chutung Chen (TW); Wen-Yung Yeh, Chutung Chen (TW); Chia-Chang KUO, Chutung Chen (TW); Sheng Pan HUANG, Chutung Chen (TW); Min Hsun HSIEH, Hsinchu City (TW); Chien Yuan WANG, Hsinchu City (TW)

(73) Assignee: EPISTAR CORPORATION, Hsinchu City (TW)

(21) Appl. No.: 13/530,608

(22) Filed: Jun. 22, 2012

Related U.S. Application Data
(63) Continuation-in-part of application No. 13/192,997, filed on Jul. 28, 2011.
Application No. 13/192,997 is a continuation-in-part of application No. 11/643,786, filed on Dec. 22, 2006, now abandoned.

(51) Int. Cl. H01L 27/15

(52) U.S. Cl. 257/89; 257/E27.12

(57) ABSTRACT

A light emitting device including a carrying element having two electric conductors connectable to a power source, a light emitting element disposed on the carrying element and electrically connected to the two electric conductors, and at least one correction element electrically connected to the light emitting element, wherein the light emitting element is adapted to provide a light source upon connection of the two electric conductors with the power source, and the at least one correction element allows the light emitting element to have functions of temperature compensation, voltage correction, or surge absorption.

### REFERENCE TO RELATED APPLICATION

This is a Continuation-in-Part of U.S. application Ser. No. 11/643,786 filed on Dec. 22, 2006 and U.S. application Ser. No. 13/192,997 filed on Jul. 28, 2011.

### FIELD OF THE INVENTION

The present invention relates to light emitting devices, and more particularly, to a light emitting device characterized by temperature compensation, voltage correction, and surge absorption.

### DESCRIPTION OF THE PRIOR ART

Lighting is indispensable to modern life and accounts for 40% of global electricity consumption. Based on optoelectronic technology, white light emitting diode (LED) bulbs are small-sized, energy-saving, durable and therefore likely to substitute for tungsten bulbs and mercury vapor bulbs in the twenty-first century to embody the notion of energy-saving, environment-friendly lighting. Over the past two decades, Taiwan ranks second behind Japan in terms of countries with the greatest LED business turnover.

An alternating current (AC) LED is composed of a plurality of light emitting diode dies, for example, that number 30 to 100. The AC LED lights up and warms up as soon as it is connected to an alternative current power source. The increase in the temperature of the AC LED brings about a shift in the voltage-current characteristic curve of the AC LED. Referring to FIG. 1, L₁ represents the voltage-current characteristic curve at temperature T₁, and the voltage-current characteristic curve L₁ shifts to a voltage-current characteristic curve L₂ as soon as temperature increases to T₂, which in turn results in a voltage drop. Given a constant operating voltage, the operating power may even double.

In more detail, when the electric current is driven into a light emitting diode die, in addition to the electric energy-photo energy conversion mechanism, part of the electric energy is transformed into the thermal energy, thus causing changes in the photoelectric characteristics. When the junction temperature (Tⱼ) of the light emitting diode die is increased from 20° C. to 80° C., the curve of the photoelectric characteristics of blue light emitting diode die and red light emitting diode die is illustrated in FIG. 2. As shown in FIG. 2, the vertical axis represents the relative value of the photoelectric characteristic value at different junction temperatures compared with that at 20° C. junction temperature of the light emitting device, such as light output power (Pₒ; rhombus symbol), wavelength shift (W_{d}; triangle symbol), and forward voltage (V_{f}; square symbol). The solid line shown in FIG. 2 represents the characteristic curve of the blue light emitting diode die, and the dotted line shown in FIG. 2 represents the characteristic curve of the red light emitting diode die. When the junction temperature is increased from 20° C. to 80° C., the light output power of the blue light emitting diode die drops about 12% and the hot/cold factor is about 0.88; the light output power of the red light emitting diode die drops about 37% and the hot/cold factor is about 0.63. Furthermore, in terms of the wavelength shift, there is no big difference between the blue light emitting diode die and the red light emitting diode die but is only slightly changed with the difference of Tⱼ. In terms of the forward voltage changes, when the junction temperature is increased from 20° C. to 80° C., the decline of the blue light emitting diode die and the red light emitting diode die is respectively about 7˜8%. Namely, the equivalent resistances of the blue light emitting diode die and the red light emitting diode die decline about 7˜8% under the operation of constant current. As mentioned above, because the temperature dependences of the blue light emitting diode die and the red light emitting diode die photoelectric characteristics are different, the undesirable phenomenon of the unstable red/blue light output power ratio happens during the period from the initial operation to the steady state. When the warm white light emitting device comprising the red light emitting diode die and the blue light emitting diode die is used in the lighting field, the light color instability during the initial state and the steady state owing to the different hot/cold factors of the blue light emitting diode die and the red light emitting diode die causes the inconvenient when using the lighting.

Furthermore, with a relatively low yield of the dies for AC LEDs, the power required for the fabricated AC LEDs usually differ from one another, and in consequence light output is different when the fabricated AC LEDs operated under the constant voltage.

Lastly, when an instantaneous power supplied by a power source, it may generate a pulse signal and tend to burn the AC LEDs.

Accordingly, an issue facing the optoelectronic industry and calling for urgent solution is to develop a light emitting diode characterized by temperature compensation, voltage correction, and surge absorption.

### SUMMARY OF THE INVENTION

In light of the aforesaid drawbacks of the prior art, it is a primary objective of the present invention to provide a light emitting device characterized by at least one of the functions of temperature compensation, voltage correction, and surge absorption.

In one embodiment of the present invention provides a light emitting device comprising a light emitting diode element; and a temperature compensation element electrically connected to the light emitting diode element. When a junction temperature of the light emitting diode element is increased from a first temperature to a second temperature during operation, the current flowing through the light emitting diode element at the second temperature is larger than the current flowing through the light emitting diode element at the first temperature.

### BRIEF DESCRIPTION OF THE DRAWINGS

FIG. 1 is a schematic view showing a shifting phenomenon of the voltage-current characteristic curve of an AC LED;

FIG. 2 illustrates the relationship curve of the junction temperature and the photoelectric characteristics of the light emitting device;

FIG. 3 is a schematic view showing the structure of the first embodiment of a light emitting device in accordance with the present invention;

FIG. 4 is a schematic view showing the structure of the light emitting element of the first embodiment of a light emitting device in accordance with the present invention;

FIG. 5(A) is a schematic view showing an exemplary circuit of the light emitting element of the first embodiment of a light emitting device in accordance with the present invention;

FIG. 5(B) is a schematic view showing a first exemplary circuit of the series-connected light emitting element and correction element of a light emitting element in accordance with the present invention;

FIG. 5(C) is a schematic view showing a second exemplary circuit of the series-connected light emitting element and correction element of a light emitting element in accordance with the present invention;

FIG. 5(D) is a schematic view showing another exemplary circuit of the light emitting element both series-connected and parallel-connected with correction elements of a light emitting element in accordance with the present invention;

FIG. 6 is a schematic view showing a structure of the second embodiment of a light emitting device in accordance with the present invention;

FIG. 7 is a schematic view showing a structure of the third embodiment of a light emitting device in accordance with the present invention;

FIGS. 8(A) and 8(C) are schematic views showing the electrical connection between a light emitting element, a correction element and a substrate of the third embodiment of a light emitting device in accordance with the present invention;

FIG. 9 is a schematic view showing a structure of the fourth embodiment of a light emitting device in accordance with the present invention;

FIGS. 10(A) and 11(B) are schematic views showing the electrical connection between a light emitting element, a correction element and a substrate of the fourth embodiment of a light emitting device in accordance with the present invention;

FIG. 12 is a schematic view showing an exemplary circuit of the fifth embodiment of a light emitting device in accordance with the present invention;

FIG. 13 is a schematic view showing an exemplary circuit of the sixth embodiment of a light emitting device in accordance with the present invention;

FIG. 14 is a schematic view showing an exemplary circuit of the seventh embodiment of a light emitting device in accordance with the present invention;

FIG. 15 is a schematic view showing an exemplary circuit of the eighth embodiment of a light emitting device in accordance with the present invention;

FIG. 16 is a schematic view showing an exemplary circuit of the ninth embodiment of a light emitting device in accordance with the present invention.

### DETAILED DESCRIPTION OF THE PREFERRED EMBODIMENTS

The following specific embodiments are provided to illustrate the present invention. Persons skilled in the art can readily gain an insight into other advantages and features of the present invention based on the contents disclosed in this specification.

Points to note are as follows: all the accompanying drawings are simple schematic diagrams intended to schematically describe the basic structure of the present invention. Hence, in the drawings, only those components related to the present invention are shown, and the shown components are not drawn according to their actual quantity, shape and dimensions when implemented; in practice, the specifications and dimensions of the components are selectively devised indeed, and the layout of the components may be far more intricate.

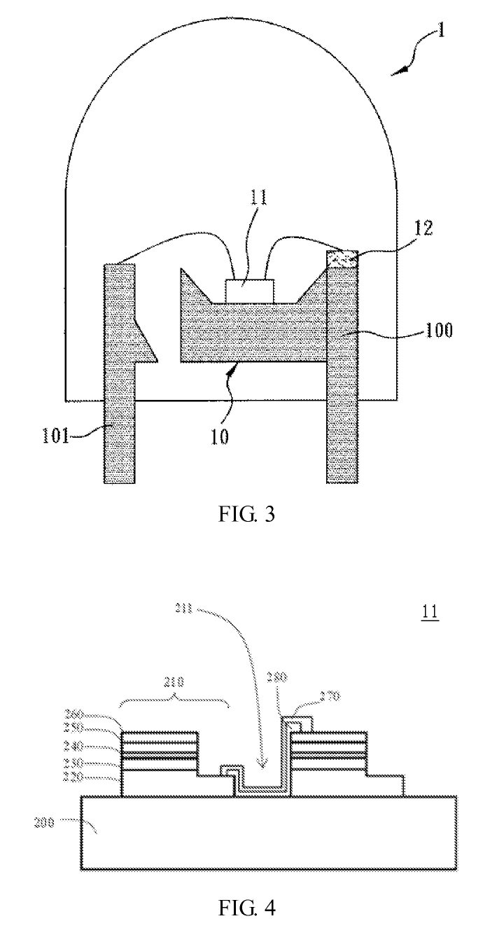

Referring to FIG. 3, the first embodiment of a light emitting device 1 of the present invention comprises a carrying element 10, a light emitting element 11, and at least one correction element 12.

The carrying element 10 is disposed with two electric conductors 100 and 101 mountable with a power source. Preferably, the carrying element 10 is a carrier. The two electric conductors 100 and 101 together form a lead frame.

The light emitting element 11 is disposed on the carrying element 10, electrically connected to the two electric conductors 100 and 101, and adapted to provide a light source upon connection of the two electric conductors 100 and 101 with the power source. The light emitting element 11 comprises a plurality of light emitting diode dies or a plurality of alternating current light emitting diode dies (AC LED).

As shown in FIG. 4, a structure diagram of the light emitting element 11 according to the above-described embodiments of the present application. A light emitting element 11 comprises a chip substrate 200, and a plurality of light emitting diode dies 210 formed or attached to the chip substrate 200 in an array type, and is divided by a trench 211. Each of the plurality of light emitting diode dies 210 comprises an n-type contact layer 220 formed on the chip substrate 200, an n-type cladding layer 230 formed on the contact layer 220, an active layer 240 formed on the n-type cladding layer 230, a p-type cladding layer 250 formed on the active layer 240, a p-type contact layer 260 formed on the p-type cladding layer 250, a connecting wire 270 electrically connected to the n-type contact layer 220 of the light emitting diode die 210 and the p-type contact layer 260 of another light emitting diode die 210 in series, and an insulation layer 280 formed between the trench 211 and the connecting wire 270 to avoid the short circuit path.

In this embodiment of the present application, the light emitting diode die 210 could be a single active-layered or double active-layered light emitting diode die. Therefore, the light emitting element 11 mentioned above is operable at a single wavelength or at least two wavelengths. In other words, the light emitting diode die 210 emits monochromic or polychromatic light. Upon connection to the power source, the light emitting element 11 provides the light source comprising visible light or invisible light (for example, ultraviolet light or infrared light).

Furthermore, the light emitting element 11 comprises a high-voltage single chip including the plurality of light emitting diode dies 210 collectively formed in an array on the single substrate, that emits blue light or red light, and the operation voltage depends on the quantity of the light emitting diode dies 210 serially connected. The material of the above-described n-type or p-type contact layer, the n-type or the p-type cladding layer, or the active layer comprises III-V group compound such as AlₓIn_{y}Ga_{(1-x-y)}N or AlₓIn_{y}Ga_{(1-x-y)}P, wherein 0≦x, y≦1; (x+y)≦1.

The at least one correction element 12 is electrically connected to the light emitting element 11 and adapted to provide the light emitting element 11 with at least one of the functions of temperature compensation, voltage correction and surge absorption upon connection of the light emitting element 11 with the power source. As shown in FIG. 3, the at least one correction element 12 is electrically connected to the light emitting element 11 in a specific way that involves disposing the correction element 12 on the electric conductor 100 attaching to the carrying element 10.

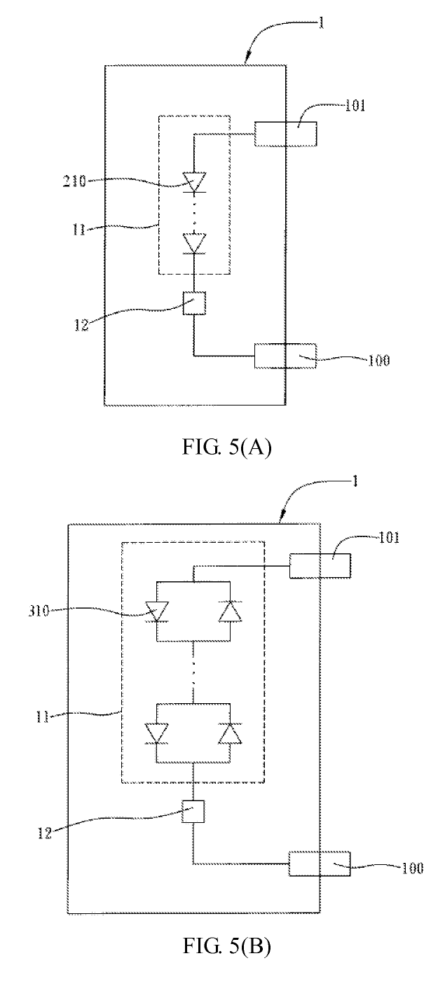

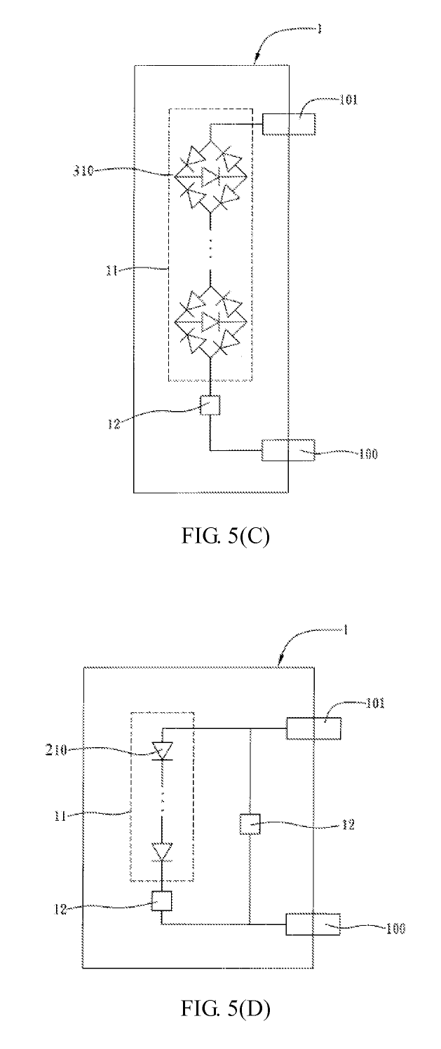

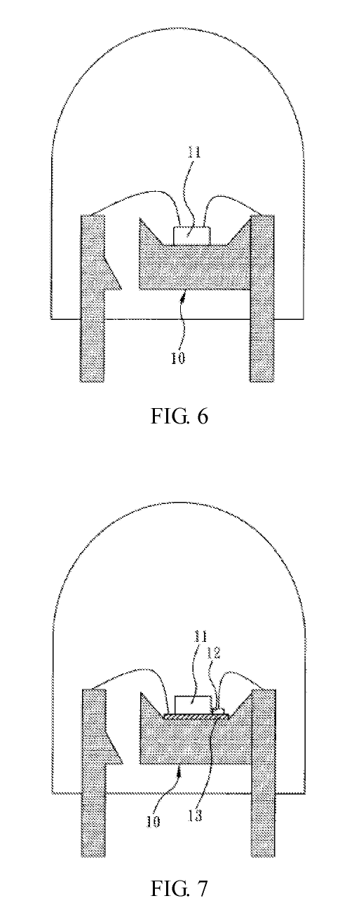

The light emitting element 11 with a plurality of light emitting diode dies 210 collectively formed thereon is connected to the correction element 12 in series by wire bonding as shown in FIG. 5(A). Upon connection of the light emitting element 11 with the power source, the correction element 12 provides at least one function selected from the group consisting of temperature compensation, voltage correction, and surge absorption. Preferably, the correction element 12 is a temperature compensation element, a voltage correction element, a surge absorption element, or an element having at least two functions selected from the group consisting of temperature compensation, voltage correction, and surge absorption.

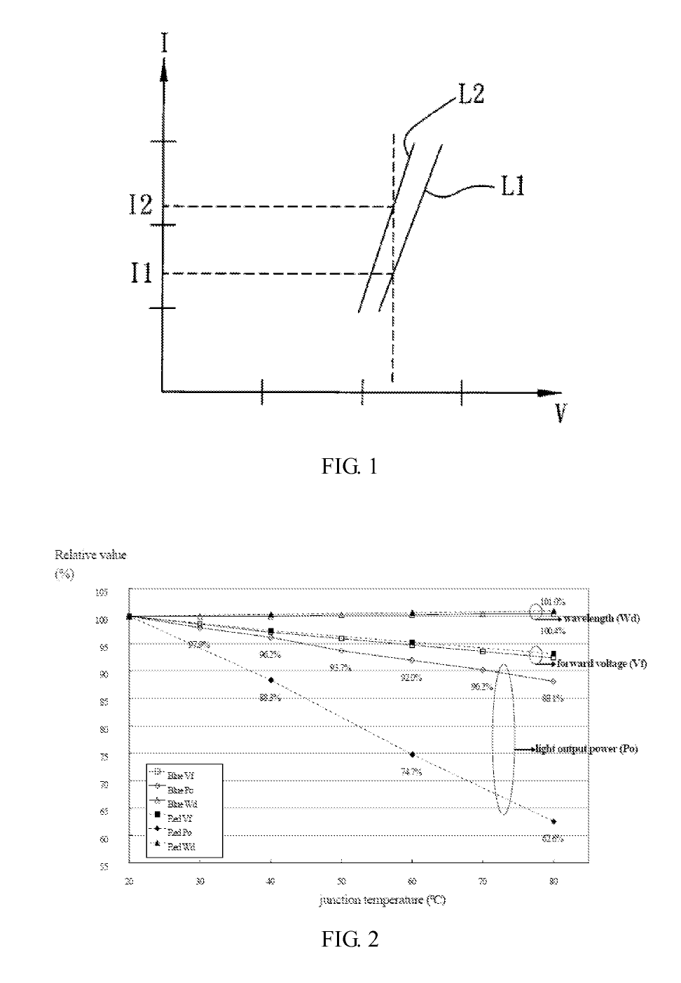

Referring to FIGS. 5(B) and 5(C), are disclosed. Where the correction element 12 is a single temperature compensation element, the correction element 12 provides temperature compensation for the light emitting element 11. The sign of the temperature coefficient of a temperature compensation element depends on the need for compensation. Under constant voltage, an increase in the temperature of the light emitting element 11 brings about an increase of current (as shown in FIG. 1, current increases from I₁ to I₂) due to leftward shifting of the voltage-current characteristic curve, and thus an increase of impedance corrects the leftward shifting of the voltage-current characteristic curve when the light emitting element 11 is implemented as a positive temperature coefficient impedance compensation element. Alternatively, a decrease in the temperature of the light emitting element 11 brings about a decrease of current due to rightward shifting of the voltage-current characteristic curve, and thus a decrease of impedance corrects the rightward shifting of the voltage-current characteristic curve when the light emitting element 11 is implemented as a negative temperature coefficient impedance compensation element.

Where the correction element 12 is a voltage correction element, the correction element 12 provides voltage correction for the light emitting element 11. Voltage correction is intended to solve a problem—with a relatively low yield of the dies for the light emitting element 11, the power required (that is, the driving biases for the light emitting element 11) usually differs from one another, and in consequence light output is different when the light emitting element 11 operated under a constant voltage. The voltage correction element can be a resistor, a capacitor, an inductor, or any element capable of absorption of voltage drop.

Where the correction element 12 is a single surge absorption element, the correction element 12 provides surge absorption for the light emitting element 11. Surge absorption is intended to solve a problem—instantaneous power supplied by a power source generates a pulse signal, which tends to burn the light emitting element 11. In this regard, the light emitting element 11 and the correction element 12 are connected in series, thereby forming an exemplary circuit shown in FIG. 5(C). The surge absorption element can be a varistor, a capacitor, a Zener diode, or an element made of varistor material (for example, ZnO).

Where the correction element 12 is an element having at least two functions selected from the group consisting of temperature compensation, voltage correction, and surge absorption, the effect of the correction element 12 remains unchanged and therefore is not described herein again. In this regard, the correction element 12 and the light emitting element 11 are connected in series and in parallel concurrently, as shown in FIG. 5(D).

As shown in FIG. 6, the schematic view shows the structure of the second embodiment of a light emitting device of the present invention, the second embodiment is similar to the first embodiment in the way that not only does the light emitting device 1 comprise the carrying element 10, the light emitting element 11, and the at least one correction element 12, but the functions and implementation of the elements remain unchanged. Referring to FIG. 6, the second embodiment only differs from the first embodiment in electrical connection (referred to as “in a specific way” in the first embodiment). The second embodiment discloses disposing the at least one correction element 12 on the light emitting element 11 by epitaxy, then wire bonding and encapsulating the at least one correction element 12 and the light emitting element 11 together (by top chip packaging), as shown in FIG. 6. The related exemplary circuit is shown in FIG. 5(A).

Referring to FIG. 7, which is a schematic view showing the structure of the third embodiment of a light emitting device of the present invention, the third embodiment is similar to the first and second embodiments in the way that not only does the light emitting device 1 comprise the carrying element 10, the light emitting element 11, and the at least one correction element 12, but the functions and implementation of the elements remain unchanged. Referring to the drawing, the third embodiment differs from the first and second embodiments in the way that the third embodiment further comprises a substrate 13 mounted with the light emitting element 11 (by flip-chip packaging).

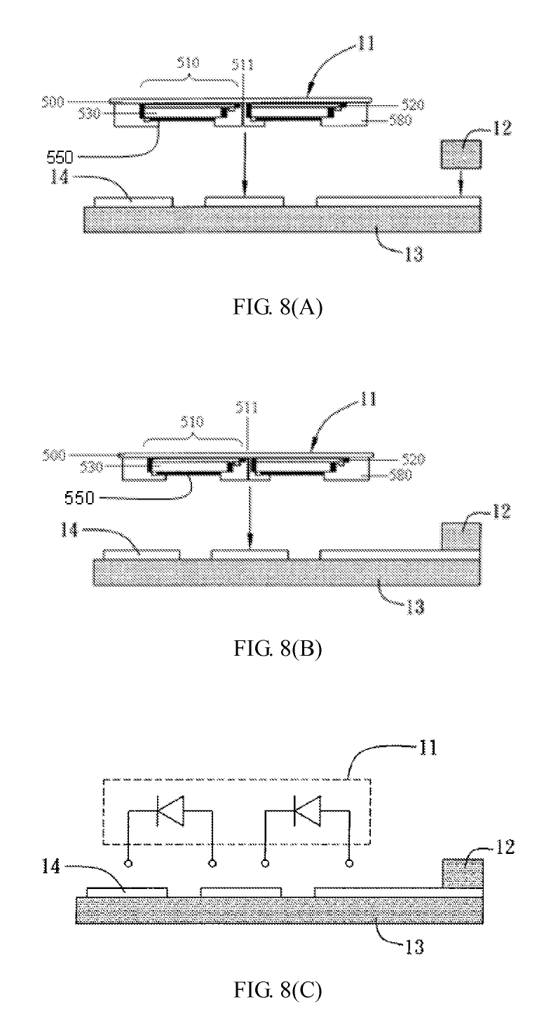

The third embodiment discloses electrically connecting the at least one correction element 12 (in a specific way) as shown in FIGS. 8(A) and 8(B). A light emitting element 11 comprises a chip substrate 500, a plurality of light emitting diode dies 510 formed or attached to the chip substrate 500 in an array, and a trench 511 dividing the plurality of light emitting diode dies 510. Each of the plurality of light emitting diode dies 510 comprises an n-type semiconductor layer 520 formed on the chip substrate 500, a p-type semiconductor layer 530 formed on the n-type semiconductor layer 520, and an active layer (not shown) formed between the n-type semiconductor layer 520 and the p-type semiconductor layer 530. Circuits 14 electrically connect the light emitting diode dies 510 to substrate 13 and bond to the light emitting diode dies 510 through bonding pads 580 by flip-chip bonding. An insulation layer 550 could be optionally formed on the light emitting diode dies 510 for avoiding the short circuit path.

The at least one correction element 12 is integrally connected to the substrate 13, and then the at least one correction element 12, the substrate 13, and the light emitting element 11 are encapsulated together as shown in FIG. 7 (as shown in the drawing, a plurality of circuits 14 are formed on the substrate 13). Referring to FIG. 8(B), the at least one correction element 12 is fabricated on the substrate 13. Then, the at least one correction element 12, the substrate 13, and the light emitting element 11 are encapsulated together as shown in FIG. 6. The related exemplary circuit is shown in FIG. 8(C).

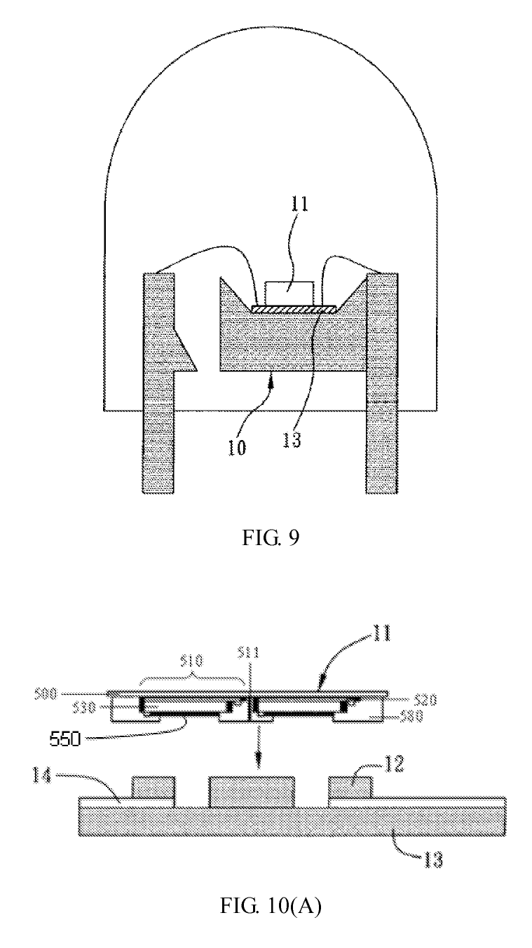

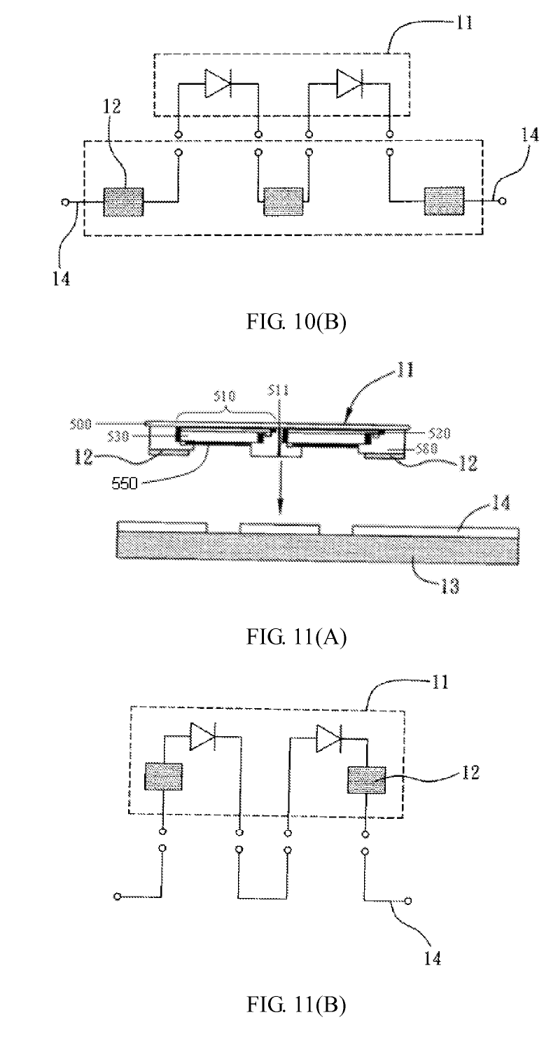

Referring to FIG. 9, which is a schematic view showing the structure of the fourth embodiment of a light emitting device of the present invention. The fourth embodiment is similar to the first, second and third embodiments in the way that not only does the light emitting device 1 comprise the carrying element 10, the light emitting element 11, and the at least one correction element 12, but the functions and implementation of the elements remain unchanged. Referring to the drawing, the fourth embodiment differs from the first, second and third embodiments in the way that the fourth embodiment not only comprises a substrate 13 mounted with the light emitting element 11 (by flip-chip packaging), but the electrical connection (referred to as “in a specific way”) of the at least one correction element 12 is new (as shown in FIGS. 10(A) and 11(A)).

Referring to FIG. 10(A), the at least one correction element 12 is disposed on the substrate 13 in the form of circuits 14. Then, the at least one correction element 12, the substrate 13, and the light emitting element 11 are encapsulated together as shown in FIG. 9. The exemplary circuit of FIG. 10(A) is shown in FIG. 10(B). Referring to FIG. 11(A), the at least one correction element 12 is disposed on the light emitting element 11 by epitaxy, and then the at least one correction element 12 and the light emitting element 11 are disposed on the substrate 13. Finally, the substrate 13, the at least one correction element 12, and the light emitting element 11 are encapsulated together as shown in FIG. 6. The exemplary circuit of FIG. 11(A) is shown in FIG. 11(B). An encapsulant for encapsulating all the aforesaid elements and components comprises metal or non-metal materials, such as ceramic, glass, resin, and transparent plastics.

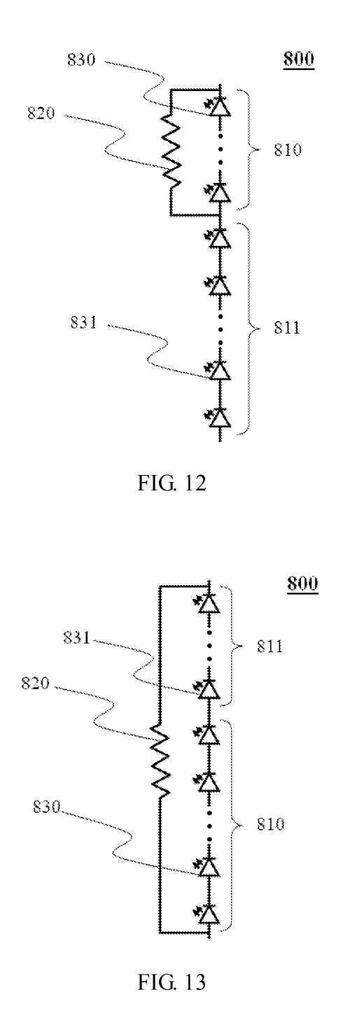

The following embodiments further discloses the light emitting device comprising different light emitting elements (i.e. light emitting modules) and at least one correction element functioning as a temperature compensation element electrically connected to the light emitting modules in detail. FIG. 12 illustrates an electric circuit diagram of the light emitting device of another embodiment according to the present application. The light emitting device 800 comprises a first light emitting module 810, a second light emitting module 811, and a thermal resistor 820 with positive temperature coefficient. The first light emitting module 810 comprises a first quantity of light emitting diode dies 830 connected to one another in series, the second light emitting module 811 comprises a second quantity of light emitting diode dies 831 connected to one another in series, and the first light emitting module 810 is electrically connected to the second light emitting module 811 in series. The light emitting diode dies 830 comprises the hot/cold factor no more than 0.9, preferably no more than 0.85, and further preferably no more than 0.8, and comprises light emitting diode dies capable of emitting visible or invisible wavelength, such as red, blue or ultraviolet wavelength light emitting diode dies, or formed by AlGaInP based material, or GaN based material. The hot/cold factor means the ratio of the light output power of the light emitting diode dies at Tⱼ=80° C. and the light output power of the light emitting diode dies at Tⱼ=20° C. when the junction temperature of the light emitting diode dies in increased from 20° C. to 80° C.

In another embodiment, the second light emitting module 811 is electrically connected to the thermal resistor 820 in parallel. The first light emitting module 810 has an equivalent internal resistance R₁, the second light emitting module 811 has an equivalent internal resistance R₂, and the thermal resistor 820 has a resistance R_{PTC}, wherein R₁ and R₂ decrease when the junction temperature is increased. As shown in FIG. 2, when the light emitting diode dies 830 are the red light or the blue light light emitting diode dies, and Tⱼ is increased from 20° C. to 80° C., R₁ and R₂ respectively decreases about 7˜8%. The resistance R_{PTC} of the thermal resistor 820 with positive temperature coefficient increases in the correlation when the temperature is increased, such as R_{PTC} increases in the linear or the non-linear correlation when the temperature is increased. During the operation of the light emitting device 800, an electric current I₁ such as 20-1000 mA flowing through the first light emitting module 810 is divided into I₂ flowing through the second light emitting module 811 and I₃ flowing through the thermal resistor 820 when I₂ flows through the second light emitting module 811 and the thermal resistor 820, wherein I₁=I₂+I₃. In addition, the potential difference of the two terminals of the second light emitting module 811 is equal to the potential difference of the two terminals of the thermal resistor 820. Namely, I₃*R_{PTC}=I₂*R₂. From the above two relationships, the electric current I₂ flowing through the second light emitting module 811 is positive-correlated to R_{PTC}/(R₂+R_{PTC}). Namely, I₂ is respectively positive-correlated to R_{PTC} and negative-correlated to R₂. In the embodiment, the junction temperature of the light emitting device 800 is increased during operation. For example, the resistance R_{PTC} of the thermal resistor 820 is increased due to the increase of the junction temperature, and the resistance R₂ of the second light emitting module 811 is decreased due to the increase of the junction temperature when the junction temperature is increased from the initial operation first temperature 20° C. to the steady state second temperature 80° C. Therefore, under the constant electric current I₁, the electric current I₂ flowing through the second light emitting module 811 is increased, and the light output power of the second light emitting module 811 is increased due to the increase of I₂. In other words, the light output power of the second light emitting module 811 can be controlled by R_{PTC} to reduce the decline of the light output power of the second light emitting module 811 caused by hot/cold factor when the junction temperature is increased, and the function of the temperature compensation is achieved.

In addition, the decline of the light output power of the light emitting device caused by hot/cold factor during the increase of the junction temperature can be offset or controlled by adjusting the quantity of the light emitting diode dies of the first light emitting module and the second light emitting module, or selecting the thermal resistor with suitable temperature coefficient. As shown in FIG. 13, the thermal resistor 820 of the embodiment can be electrically connected to the first light emitting module 810 and the second light emitting module 811 in parallel at the same time. Thus, the electric current flowing through the first light emitting module 810 and the second light emitting module 811 is increased compared with that at the initial temperature when the junction temperature of the light emitting device is increased.

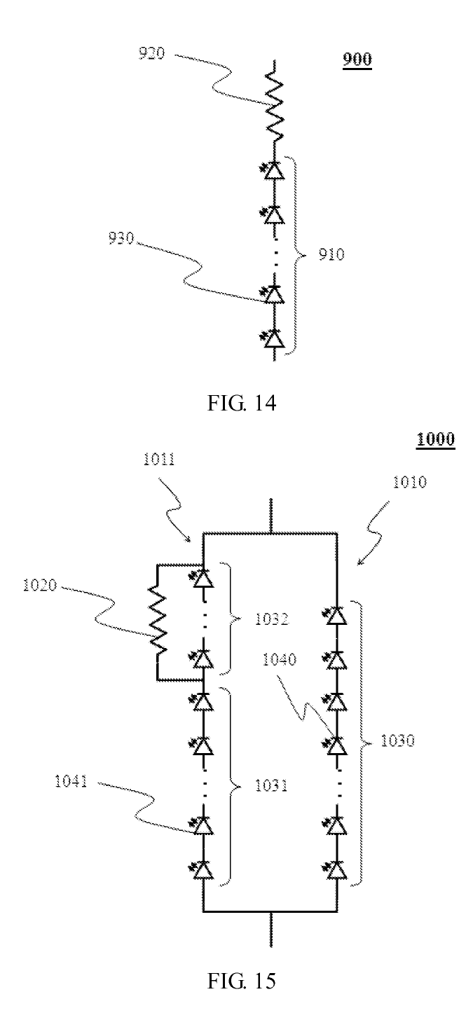

FIG. 14 is an electric circuit diagram of the light emitting device of another embodiment according to the present application. The light emitting device 900 comprises a light emitting module 910 and a thermal resistor 920 with negative temperature coefficient. The light emitting module 910 comprises a plurality of light emitting diode dies 930 connected to one another in series. The light emitting module 910 comprises the light emitting diode dies 930 capable of emitting visible or invisible wavelength, such as red, blue or ultraviolet wavelength light emitting diode dies, or formed by AlGaInP-based material, or GaN-based material.

In the embodiment, the light emitting module 910 and the thermal resistor 920 are electrically connected in series. The light emitting module 910 has an equivalent internal resistance R₁, and the thermal resistor 920 has a resistance R_{NTC}, wherein R₁ decreases when the junction temperature is increased. As shown in FIG. 2, when the light emitting diode dies 930 are the red light or the blue light light emitting diode dies, and Tⱼ is increased from 20° C. to 80° C., R₁ decreases about 7˜8%. The resistance R_{NTC} of the thermal resistor 920 with negative temperature coefficient decreases in a correlation when the temperature is increased, such as R_{NTC} decreases in the linear or the non-linear relationship when the temperature is increased. When the light emitting device 900 is operated under the constant electric voltage, the electric current I₁ flowing through the light emitting module 910 is about 20-1000 mA under the input Vᵢₙ of constant electric voltage. According to Ohm's law, the electric current I₁ is inversely proportional to the total resistance of the light emitting device 900 and the input voltage Vᵢₙ, that is, I₁=Vᵢₙ/(R₁+R_{NTC}). In other words, the electric current Iᵢ flowing through the light emitting module 910 is negative-correlated to R_{NTC} and R₁. In the embodiment, the junction temperature of the light emitting device 900 is increased during operation. For example, the resistance R_{NTC} of the thermal resistor 920 and the resistance R₁ of the light emitting module 910 are decreased due to the increase of the junction temperature when the junction temperature is increased from the initial operation first temperature 20° C. to the steady state second temperature 80° C. Thus, I₁ is increased, and the light output power of the light emitting module 910 is increased due to the increase of I₁. In other words, the light output power of the light emitting module 910 can be controlled by the R_{PTC} to reduce the decline of the light output power of the light emitting module 910 caused by hot/cold factor when the junction temperature is increased, and the function of the temperature compensation is achieved. In addition, the decline of the light output power of the light emitting device caused by hot/cold factor during the increase of the junction temperature can be reduced by adjusting the quantity of the light emitting diode dies of the light emitting module 910, and/or selecting the thermal resistor with suitable temperature coefficient.

FIG. 15 is an electric circuit diagram of the light emitting device of another embodiment according to the present application. The light emitting device 1000 comprises a first light emitting module 1010, a second light emitting module 1011 connected to the first light emitting module 1010 in parallel, and a thermal resistor 1020 with positive temperature coefficient electrically connected to the second light emitting module 1011. The first light emitting module 1010 comprises a first light emitting group 1030, and the second light emitting module 1011 comprises a second light emitting group 1031 and a third light emitting group 1032. The first light emitting group 1030 comprises a first quantity of the first light emitting diode dies 1040 connected to one another in series, the second light emitting group 1031 comprises a second quantity of the second light emitting diode dies 1041 connected to one another in series, and the third light emitting group 1032 comprises a third quantity of the second light emitting diode dies 1041 connected to one another in series. The thermal resistor 1020 is electrically connected to the third light emitting group 1032 in parallel, and electrically connected to the second light emitting group 1031 in series. The first light emitting module 1010 or the first light emitting diode die 1040 has the hot/cold factor more than 0.85; the second light emitting module 1011 or the second light emitting diode die 1041 has the hot/cold factor less than that of the first light emitting module 1010 or the first light emitting diode die 1050, for example less than 0.85, or preferably less than 0.8. In the embodiment, the first light emitting diode dies 1040 comprises the blue light light emitting diode dies with the hot/cold factor about 0.88, and the second light emitting diode dies 1041 comprises the red light light emitting diode dies with the hot/cold factor about 0.63. Other visible or invisible wavelength light emitting diode dies can also be included, such as green, yellow or ultraviolet wavelength light emitting diode dies, or formed by AlGaInP based material, or GaN based material.

In the embodiment, the third light emitting group 1032 is electrically connected to the thermal resistor 1020 in parallel. The second light emitting diode group 1031 has an equivalent internal resistance R₁, the third light emitting group 1032 has an equivalent internal resistance R₂, and the thermal resistor 1020 has a resistance R_{PTC}, wherein R₁ and R₂ decrease when the junction temperature is increased. As shown in FIG. 2, when the second light emitting diode dies are the red light or the blue light light emitting diode dies, R₁ and R₂ respectively decreases about 7˜8%. The resistance R_{PTC} of the thermal resistor 1020 with positive temperature coefficient increases in the correlation when the temperature is increased, such as R_{PTC} increases in the linear or the non-linear correlation when the temperature is increased. During the operation of the light emitting device 1000, an electric current I₀ is divided into I₁ flowing through the first light emitting module 1010 and I₂ flowing through the second light emitting module 1011. The electric current I₂ flowing through the third light emitting group 1032 and the thermal resistor 1020 of the second light emitting module 1011 is divided into I₃ flowing through the third light emitting group 1032 and I₄ flowing through the thermal resistor 1020, wherein I₂=I₃+I₄. In addition, the potential difference of the two terminals of the third light emitting group 1032 is equal to the potential difference of the two terminals of the thermal resistor 1020. Namely, I₄*R_{PTC}=I₃*R₂. From the above two relationships, the electric current I₃ flowing through the third light emitting group 1032 is positive-correlated to R_{PTC}/(R₂+R_{PTC}). Namely, I₃ is positive-correlated to R_{PTC} and negative-correlated to R₂. In the embodiment, the junction temperature of the light emitting device 1000 is increased during operation. For example, the resistance R_{PTC} of the thermal resistor 1020 is increased due to the increase of the junction temperature, and the resistance R₂ of the third light emitting group 1032 is decreased due to the increase of the junction temperature when the junction temperature is increased from the initial operation first temperature 20° C. to the steady state second temperature 80° C. Therefore, I₃ increases due to the increase of the junction temperature and the light output power of the third light emitting diode group 1032 also increases due to the increase of I₃. In the embodiment, the hot/cold factor of the first light emitting module 1010 is larger than that of the second light emitting module 1011, so the decline of the light output power of the second light emitting module 1011 is larger than that of the first light emitting module 1010 when the junction temperature is increased. Thus, the light color mixed by the light emitted from the first light emitting module 1010 and the light emitted from the second light emitting module 1011 shifts to the light color emitted from the first light emitting module 1010 when the junction temperature is increased. But the decline of the light output power of the second light emitting module 1011 caused by hot/cold factor can be reduced when the junction temperature is increased by controlling the R_{PTC} of the thermal resistor 1020, and the function of the temperature compensation can be achieved. In addition, the decline of the light output power of the second light emitting module 1011 caused by hot/cold factor during the increase of the junction temperature can be offset or controlled by adjusting the quantity of the light emitting diode dies of the second light emitting group and the third light emitting group, or selecting the thermal resistor with suitable temperature coefficient. Furthermore, the thermal resistor 1020 of the embodiment can be electrically connected to the second light emitting group 1031 and the third light emitting group 1032 in parallel at the same time. Thus, the electric current flowing through the second light emitting group 1031 and the third light emitting group 1032 is increased compared with that at the initial temperature when the junction temperature of the light emitting device is increased.

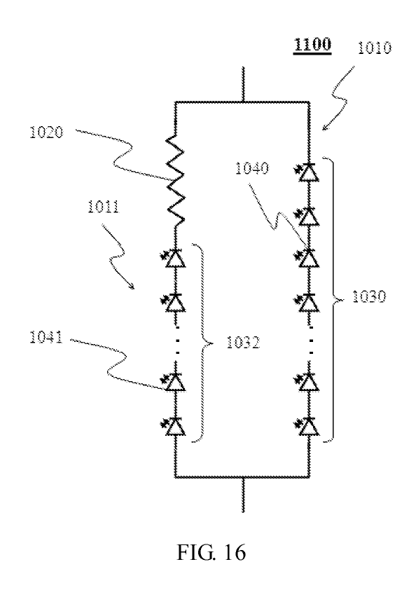

Another embodiment of the present application is illustrated in FIG. 16. The difference between the embodiments shown in FIGS. 14 and 15 is that the second light emitting module 1011 is connected to the thermal resistor 1020 with negative temperature coefficient in series. Based on the related description similar to the embodiments disclosed in FIGS. 13 and 14, the function of temperature compensation of the present application is achieved. In addition, the first light emitting module and the second light emitting module of the above-described embodiments shown in FIGS. 14 and 15 are not limited to be connected in parallel, and each of them also can be connected to an independent control current source or voltage source.

As described above and shown in the drawings, the present invention discloses a light emitting device comprising a light emitting element and at least one correction element electrically connected to the light emitting element. Upon connection of the light emitting device with a power source, the light emitting element provides at least one function selected from the group consisting of temperature compensation, voltage correction, and surge absorption. Preferably, the light emitting element provides all the functions, namely temperature compensation, voltage correction, and surge absorption and thereby solves the following drawbacks of the prior art: current and power (which should otherwise be well-controlled and fall within a safe range) increase because of current-voltage shift resulting from a temperature change; and, with a relatively low yield of the dies for a light emitting element, the power sources (that is, the driving biases for the light emitting element) usually differ from one another, and in consequence light sources are seldom homogenous when operated under constant voltage. Advantages of the present invention are as follows: production yield increases, because dies of different biases can be fabricated and finished at the same level of production; and a light emitting device of the present invention is burn-resistant, because any pulse signal generated by instantaneous power supplied by a power source is readily absorbed (that is, power surge resistance).

The aforesaid embodiments merely serve as the preferred embodiments of the present invention. They should not be construed as to limit the scope of the present invention in any way. Hence, any other changes can actually be made in the present invention. It will be apparent to those skilled in the art that all equivalent modifications or changes made, without departing from the spirit and the technical concepts disclosed by the present invention, should fall within the scope of the appended claims.

1. A light emitting device, comprising:
a substrate having circuits;
a light emitting element disposed on the substrate; and
at least one temperature compensation element electrically connected to the light emitting element such that the current flowing through the light emitting element at a first temperature is larger than the current flowing through the light emitting element at a second temperature;
wherein the first temperature is higher than the second temperature.

2. The light emitting device of claim 1, wherein the light emitting element comprises a first light emitting module and a second light emitting module, the first light emitting module comprises a first hot/cold factor and the second light emitting module comprises a second hot/cold factor, and the temperature compensation element is adapted to reduce the difference of the first hot/cold factor and the second hot/cold factor.

3. The light emitting device of claim 2, wherein the first light emitting module is composed of a plurality of blue light emitting diode dies and/or the second light emitting module is composed of a plurality of red light emitting diode dies.

4. The light emitting device of claim 1, wherein the emitted light of the light emitting device is warm white.

5. The light emitting device of claim 1, wherein the light emitting element is flip-chip bonded to the circuits of the substrate.

6. The light emitting device of claim 1, further comprising a carrier element having two electric conductors connectable to a power source, and the substrate disposed on the carrying element.

7. The light emitting device of claim 6, wherein the two electric conductors comprise lead frames.

8. The light emitting device of claim 1, wherein the light emitting element comprises a plurality of light emitting diode dies.

9. The light emitting device of claim 8, wherein the plurality of light emitting diode dies is serially or parallel connected through the circuits of the substrate.

10. The light emitting device of claim 1, wherein the light emitting element comprises a plurality of alternative-current light emitting diode dies (AC LED).

11. The light emitting device of claim 1, wherein the correction element is electrically connected to the light emitting element by a series connection.

12. The light emitting device of claim 1, wherein the correction element is electrically connected to the light emitting element by a parallel connection.

13. The light emitting device of claim 12, wherein the temperature compensation element is a thermal resistor with a positive temperature coefficient.

14. The light emitting device of claim 11, wherein the temperature compensation element is a thermal resistor with a negative temperature coefficient.

15. The light emitting device of claim 1, wherein the at least one correction element is encapsulated together with the substrate and the light emitting element.
